(19) United States
(12) Patent Application Publication
(10) Pub. No.: US 2026/0090391 A1
(43) Pub. Date: Mar. 26, 2026

(54) INNER DIE HAVING ESD PROTECTION DEVICE IN 3D PACKAGING

(71) Applicant: Taiwan Semiconductor Manufacturing Co., Ltd., Hsinchu (TW)

(72) Inventors: Jen-Yuan CHANG, Hsinchu (TW); Yi-Chen LI, Hsinchu (TW)

(21) Appl. No.: 18/892,212

(22) Filed: Sep. 20, 2024

(51) Int. Cl. H01L 23/60; H01L 23/00; H01L 23/48; H01L 25/18

(52) U.S. Cl. CPC H10W 42/60; H10W 20/20; H10W 90/00; H10W 90/22

(57) ABSTRACT

A package includes a first die and a second die stacked vertically over one another. A first surface of the first die facing a second surface of the second die. The first die includes an ESD protection device. The ESD protection device includes a conductive pattern adjacent to the first surface of the first die and an interconnect structure connected to the conductive pattern and extending toward a first semiconductor substrate of the first die that is opposite to the first surface of the first die.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area.

In addition to smaller electronic components, improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth due to the decreased length of interconnects between the stacked chips. However, there are many challenges related to three-dimensional devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 shows an example semiconductor die, in accordance with some embodiments.

FIG. 1A shows an example semiconductor die, in accordance with some embodiments.

FIG. 1B shows an example semiconductor die, in accordance with some embodiments.

FIG. 2 shows an example semiconductor die, in accordance with some embodiments.

FIG. 3 shows an example conductive pattern, in accordance with some embodiments.

FIG. 4 shows an example conductive pattern, in accordance with some embodiments.

FIG. 4A shows example conductive patterns, in accordance with some embodiments.

FIG. 5 shows an example semiconductor die, in accordance with some embodiments.

FIG. 6 shows an example conductive pad, in accordance with some embodiments.

FIG. 7 shows an example 3D package, in accordance with some embodiments.

FIGS. 8A-8D show examples of die stacks, in accordance with some embodiments.

FIG. 9 shows an example process, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are directed to a base or interconnection device die in a 3D packaging structure that includes interconnection structures with additional dies connected therewith, such as a system on integrated chip (SoIC) packaging design and structure.

The massive scale of modern data, such as analytics data or AI programming, easily overwhelms memory and computation resources on computational servers. For example, deriving meaningful insights from big data requires rich analytics. The big data and AI sectors demand ever increasing throughput to extraordinary large volumes of data. This is true both with respect to the exponential rise in the volume of data itself and to the increasing number and complexity of formats of data that such platforms must manage. AI and big data chipsets today are required to manage not just relational data, but also text, video, image, emails, social network feeds, real time data streams, sensor data, etc.

Embodiments of the present disclosure include an interconnection device die and SoIC architecture that addresses such demands and design parameters. Embodiments disclosed herein are provided to reduce the distance between processors and memories, increase the number of device-to-device (“D2D”) connections in the packaging, and provide high bandwidth (“HB”) memory capable of meeting the increasing demands with respect to memory access and bandwidth, real time processing and data delivery, and reduced power consumption.

A device die is provided as an interconnection device die, also referred to herein as a “base die” or “interconnection die. ” The interconnection device die provides a structure on which other device dies, e.g., integrated circuit dies, such as SOICs, 3DICs, processors, or the like can be supported and interconnected.

An integrated fan out (“InFO”) structure may include a circuit that provides connectivity between dies in a compact design. The InFO structure may include at least one redistribution layer (RDL) structure embedded in at least one insulating encapsulation of a device die, where the redistribution circuit structure includes one or more conductors electrically connected to conductive terminals arranged on a surface of the device die. As used herein, a semiconductor body may include a die or multiple semiconductor dies coupled, e.g., bonded or stitched, together.

A SoIC structure may include active dies stacked one on top of another. The active dies may be interconnected vertically using through-silicon via (“TSV”) structures. A SoIC structure may be a three-dimensional integrated circuit (“3DIC”). For example, a 3DIC may include a stack of similar active dies, such as a stack of memory dies with a controller logic on a separate die (e.g., a bottom die). In some embodiments, the 3DIC may include a stack of different dies. The dies may be stacked face to back (F2B), one on top of the other, with their active areas facing downwards or upwards. In some embodiments, the lower die may include metallization on a back surface of a substrate, and electrical connectors such as metal bumps, that may be used to connect the top die to this metallization. TSV structures may pass through the lower die's substrate and connect the metal bumps on the top die, via the back-side metallization, to the active area of the second die. In some embodiments, the dies may be stacked face to face (F2F). In such embodiments, the active areas of the lower die and the upper die face each other with electrical connectors providing connectivity between the opposing dies. In a F2F structure, a TSV structure may pass through one die, such as the lower die, and metallization or redistribution circuit may be formed on the back thereof to provide connection to components of the package.

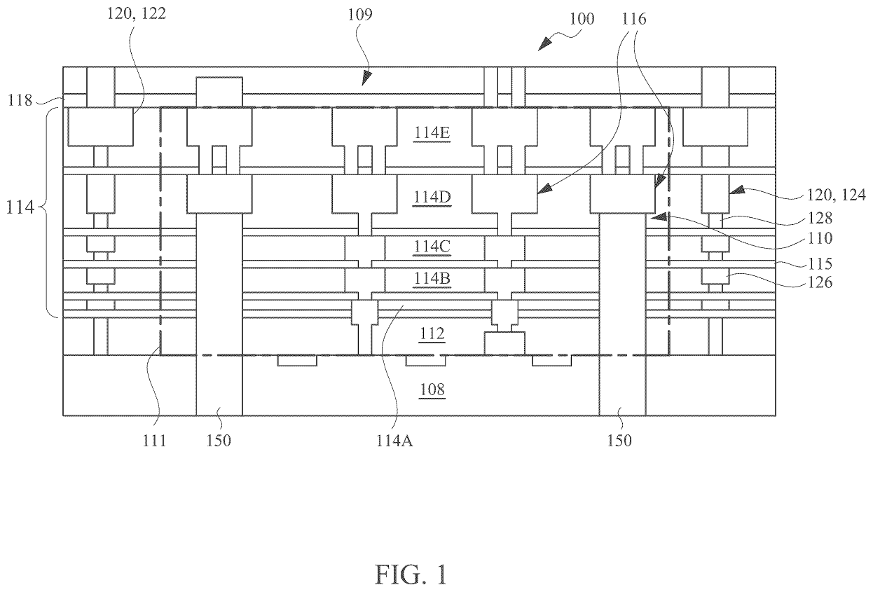

FIG. 1 is a cross-sectional view of a semiconductor die 100, according to various example embodiments of the present disclosure. Referring to FIG. 1, the semiconductor die 100 includes a first semiconductor substrate (or base semiconductor substrate) 108 and various back-end-of line BEOL structures 110. In some embodiments, the first semiconductor substrate 108 may include an elementary semiconductor such as silicon or germanium and/or a compound semiconductor such as silicon germanium, silicon carbide, gallium arsenic, indium arsenide, gallium nitride or indium phosphide. In some embodiments, the first semiconductor substrate 108 may be a semiconductor-on-insulator (SOI) substrate. In various embodiments, the first semiconductor substrate 108 may take the form of a planar substrate, a substrate with multiple fins, nanowires, or other forms known to people having ordinary skill in the art. Depending on the requirements of design, the first semiconductor substrate 108 may be a P-type substrate or an N-type substrate and may have doped regions, e.g., P-well or N-well, therein. The doped regions may be configured for an N-type device or a P-type device.

In some embodiments, the first semiconductor substrate 108 includes isolation structures, e.g., shallow trench isolations STI, defining at least one active area, and a first device layer may be disposed on/in the active area. The first device layer 111 may include a variety of devices. In some embodiments, the variety of devices may include active components, passive components, or a combination thereof. In some embodiments, the first semiconductor substrate 108 may include circuit components that form a memory array or other memory structure. In some embodiments, the first semiconductor substrate 108 may include circuit components that provide non-memory functionality, such as communication, logic functions, processing, or the like. In some embodiments, the devices may include integrated circuits devices. The devices may be, for example, transistors, capacitors, resistors, diodes, photodiodes, fuse devices, or other similar devices. In some embodiments, the first device layer includes gate electrodes, source or drain regions, spacers, and the like.

The BEOL structures 110 includes layers stacked on the substrate 108 till a surface 109 of the die 100 opposite to the substrate 108. The BEOL structures 110 may include an inter-layer dielectric (ILD) 112, one or more inter-metal dielectric (IMD) layers 114 (e.g., 114A, 114B, 114C, 114D, 114E shown on FIG. 1), various metal features 116 including one or more ESD protection devices 120, and a passivation layer 118. In some embodiments, the ILD 112 may be formed of a dielectric material such as silicon oxide (SiO2) silicon nitride (SiN or Si3N4), silicon carbide (SiC), or the like, and may be deposited by any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like.

The IMD layers 114 may include an extra low-k (ELK) dielectric material having a dielectric constant (k) less than about 2.6, such as from 2.5 to 2.2. In some embodiments, ELK dielectric materials include carbon-doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials may include porous versions of existing dielectric material, such as porous hydrogen silsesquioxane (HSQ), porous methyl silsesquioxane (MSQ), porous polyarylether (PAE), porous SiLK, or porous SiO2. The IMD layers 114 may be formed by any suitable deposition process. In some embodiments, the IMD layers 114 may be deposited by a PECVD process or by a spin coating process.

The metal features 116 may include wires, lines and via structures. The metal features 116 may be formed of any suitable electrically conductive material, such as tungsten (W), copper (Cu), a copper alloy, aluminum (Al), an aluminum alloy, silver, gold, combinations thereof, or the like. Other suitable electrically conductive materials, e.g., conductive nitride compounds, are also possible and within the scope of disclosure.

Some of the metal features 116 may be electrically connected to the devices or connection pad on the substrate 108, such that the metal features may electrically connect semiconductor devices formed on the first semiconductor substrate 108.

The ESD protection device(s)120 may include a conductive pattern 122 adjacent to adjacent to the surface 109 and an interconnect structure 124 that is connected to the conductive pattern 122 and extends to the substrate 108 and/or another feature or layer that can function as a grounding node. For example, electrostatic discharges on the surface 109 may be caught be the conductive feature and routed to the substrate or the grounding node. For example, the interconnect structure 124 of the ESD protection device 120 may extend through the dielectric layers such as ILD 112, IMD layers 114, and reach the substrate 108, e.g., the P-well or N-well doped regions in the substrate 108 or undoped regions of the substrate 108. In some embodiments, the interconnect structure 124 may be in electrical contact with a circuit element formed on the substrate 108. For example, the interconnect structure 124 may be electrically coupled to a ground terminal formed on the substrate 108.

In some implementations, as shown in FIG. 1A, the semiconductor die 100 may include multiple to ESD protection devices 120 electrically coupled to different features in the substrate 108 and/or to different circuit features, e.g., an N-type device or an P-type device, formed on the substrate 108. For example, FIG. 1A shows that three ESD protection devices 120 are coupled to an N well in a P region, an P well in an N region, or a ground region G in the substrate 108, respectively.

In some element, the conductive pattern 122 is formed as a part of the metallization level that is most adjacent to the surface 109, e.g., the last or top metallization level in the BEOL structure 110 of the semiconductor die 100. Proximity to the surface 109 facilitates attraction of electrostatic discharges on the surface 109 or on surfaces adjacent to the surface 109, e.g., a surface of another body bonded to the die 100. Such electrostatic discharges may occur due to charge buildup during a plasma etch process, a deposition process, or a bonding process in which the die 100 is bonded to and attached to another body, either another semiconductor die or a carry substrate. The interconnect structure 124 of the ESD protection device 120 may include line or pad structures 126 as parts of each metallization levels and via structures 128 that electrically couple the line or pad structures to one another. The ESD protection device 120 may be electrically isolated from one or more of the other metal features 116

Each of the conductive pattern 122 or the line or pad structure 126 of the ESD protection device 120 may include a same conductive material of the respective metallization level, e.g., copper, aluminum, silver or gold. The via structures 128 may be a same conductive material as the line or pad structures 126 or may be a different conductive material. For example, the via structures 128 may be copper at an atomic percentage greater than 80%, such as greater than 90% or greater than 95%, although greater or lesser percentages may be used.

In some embodiments, the die 100 may include one or more through silicon via (TSV) structures 150. The TSV structures 150 may extend into and/or through the first semiconductor substrate 108, the IDL 112, and one or more of the IMD layers 114, to electrically connect the metal features 116 to elements formed on the first semiconductor substrate 108 and/or elements of adjacent dies. The TSV structures 150 may be formed of an electrically conductive material. For example, the TSV structures 150 may include copper at an atomic percentage greater than 80%, such as greater than 90% or greater than 95%, although greater or lesser percentages of copper may be used. Other suitable electrically conductive metal materials are within the scope of disclosure.

In some embodiments, the metal features 116 including the ESD protection device 120 may be formed by a dual-Damascene process or by multiple single Damascene processes. Single-Damascene processes generally form and fill a single feature with a metal material, e.g., copper, per Damascene stage. Dual-Damascene processes generally form and fill two features with copper at once, e.g., a trench and overlapping through-hole may both be filled with a single copper deposition using dual-Damascene processes. In some embodiments, the metal features 116 including the ESD protection device 120 may be formed by an electroplating process.

For example, the Damascene processes may include patterning the dielectric layers, e.g., ILD 112 and/or IMD layers 114, to form openings, such as trenches and/or though-holes, e.g., via holes. A deposition process may be performed to deposit a conductive metal, e.g., copper, in the openings. A planarization process, such as chemical-mechanical planarization (CMP) may then be performed to remove excess metal, e.g., copper.

For example, the patterning, metal deposition, and planarizing processes may be performed for each of the dielectric layers, e.g., ILD 112 or IMD layers 114, in order to form the metal features 116 including relevant portions of the ESD protection device 120 therein. For example, the ILD 112 may be deposited and patterned to form openings, e.g., via hole or trenches. A deposition process may then be performed to fill the openings in the ILD layer 112 with a conductive material. A planarization process may then be performed to remove the overburden. The above deposition, patterning, and planarization processes may be repeated to form IMD layers 114A-114E and the corresponding portions of the metal features 116 including the ESD protection device 120 disposed therein.

In some embodiments, barrier layers (not shown) may be disposed between the ILD 112 or IMD layers 114, and the metal features 116 including the ESD protection device 120, and/or the TSV structures 150, to prevent metal diffusion into the first semiconductor substrate 108 and/or ILD 112 and/or IMD layers 114. The barrier layer may include Ta, TaN, Ti, TiN, CoW, or combinations thereof, for example. Other suitable barrier layer materials are within the contemplated scope of disclosure.

The ESD protection devices 120 or the conductive patterns 122 thereof may be positions on or adjacent to various surface regions of surface 109 of the die 100, where electrostatic charges are expected to accumulate in the handling of the die 100, e.g., in the assembly process. For example, as shown in FIG. 1B, the conductive patterns 122 of the ESD protection devices 120 may be positioned on edges, corners, at a center, or along a center line of the surface 109 of the die 100, where it is expected that electrostatic charges may accumulate in the handling of the die 100 in a packaging process. Other positions of the ESD protection device 120 are also possible and included in the scope of the disclosure.

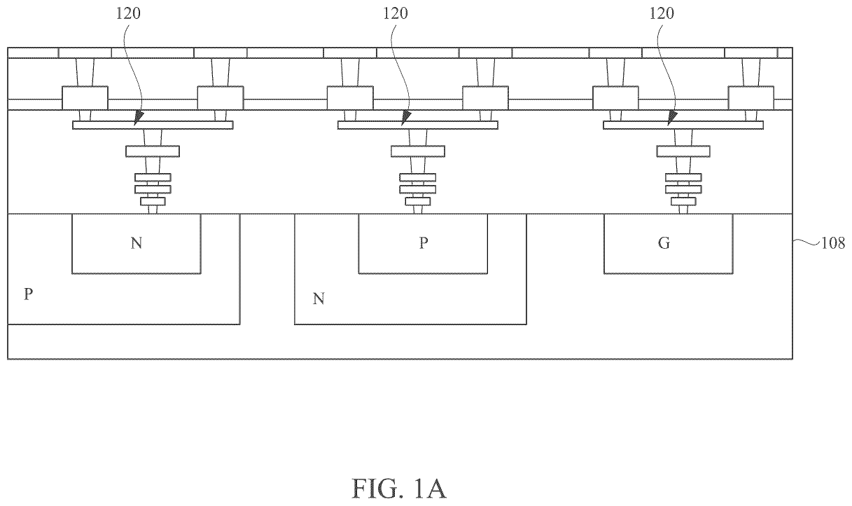

FIG. 2 shows, in a cross-section view, an example ESD protection device 120. As shown in FIG. 2, the ESD protection device 120 may include conductive pads 132 arranged on a redistribution “RDL” layer 130. The RDL layer 130 includes (not specifically shown for simplicity) metal traces and insulating layers, redistributing I/O connections for bonding the die 100 to another die or a carry substrate in a fan-out or 3D packaging process. The structure of the RDL layer 130 can also incorporate vias that enable the interconnection of the redistribution traces and the underlying layers, ensuring proper signal routing and minimizing signal losses. As shown in FIG. 2, in some embodiments, the conductive pads 132 are coupled to the conductive pattern 122 through vias 134. In some embodiments, the conductive pads 132 include a same conductive material, e.g., aluminum, as other metal features, e.g., metal traces, of the RDL layer 130. The vias 134 may include a same or a different conductive material from that of the conductive pad 132. For example, the vias 134 are copper.

The RDL layer 130 may be formed using various approaches, e.g., a polymer-based process or a metal Damascene process, which are all included in the scope of the disclosure.

In some embodiments, the conductive pattern 122 and/or the conductive pads 132 on the RDL layer 130 of the ESD protection device 120 are fully embedded within the and under the surface 109 of the die 100. For example, a dielectric layer 136 is positioned between the ESD protection device 120 and the front surface 109.

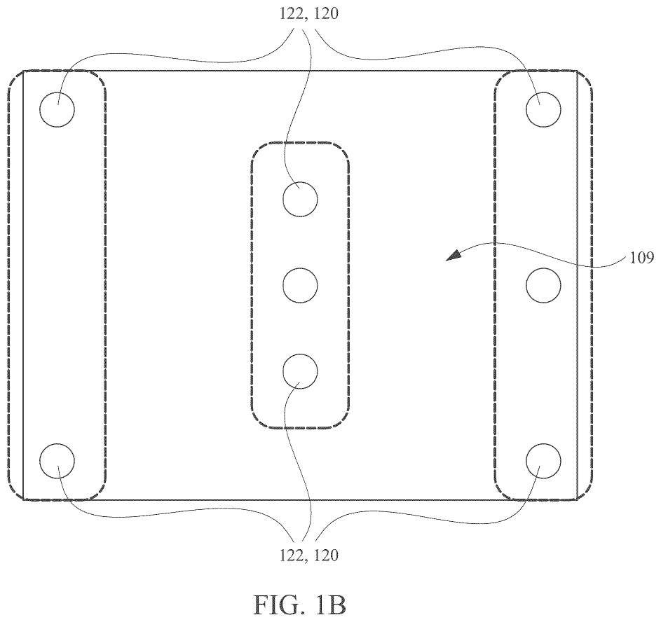

FIG. 3 shows in a top view a conductive pattern 122 and the related conductive pads 132. As shown in FIG. 3, in some embodiments, the conductive pattern 122 may include one or more comb-shaped patterns or structures 140 and one or more bridge patterns or structures 142 that each connects to one or more or comb-shaped patterns or structures 140. For example, a bridge pattern or structure 142 may connect two comb-shaped patterns or structures 140 together. One or more of the comb-shaped patterns or structure 140 or the bridge patterns or structures 142 are connected to the interconnect structure 124. FIG. 3 shows, as an example, that the interconnect structure 124 is in direct contact with a bridge pattern or structure 142, which does not limit the scope of the disclosure. In some embodiments, the interconnect structure 124 may be in direct contact with a comb-shaped pattern or structure 140. In some embodiments, a comb-shaped patten or structure 140 is not connected to a bridge pattern or structure 124.

The comb-shaped pattern or structure 140 may include a plurality of comb fingers 144. In some embodiments, each of the conductive pads 132 is coupled to a comb finger 144 through a via 134. In some embodiments, multiple conductive pads 132 are coupled to a same comb finger 144. In some embodiments, one or more comb fingers 144 are not coupled to any conductive pad 132. In some implementations, a width D1 of a comb finger 144 is greater than or equal to 0.1 μm. In some implementations, a distance D2 between two adjacent comb fingers 144 is greater than or equal to 0.1 μm. Other dimensional parameters of the width or distance of the comb fingers 144 are also possible and included in the scope of the disclosure.

In some implementations, the conductive pattern 122 maybe formed as part of a metal layer of other functional metal features. For example, the conductive pattern 122 may be formed in a same layer or level as a bonding metal layer, a redistribution layer (e.g., of aluminum), a die top metal layer or a inter-metal layer that is adjacent to the surface 109 of the die 100.

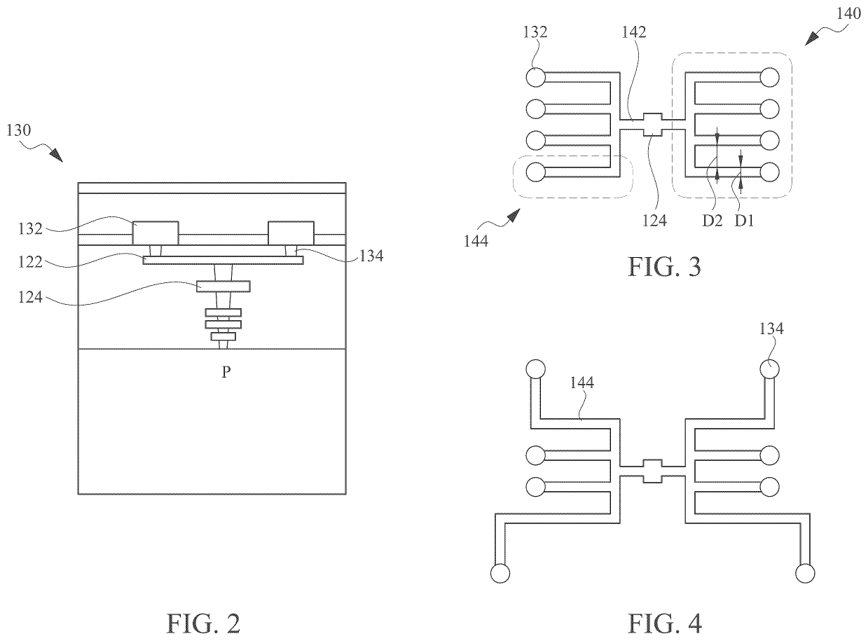

The comb fingers 144 may include a uniform shape, e.g., a rectangular shape, or may include varied shapes. As shown in FIG. 4, a comb-shaped pattern or structure 140 may include comb fingers 144 with non-uniform shapes and varied finger lengths or other dimensions, which may be configured based on maps of ESD charges on various surface regions of the surface 109 and/or on various surface regions of another semiconductor die or body to be bonded to the die 100 in a packaging process.

The shape of the conductive pattern 122 can be configured to facilitate catching of electrostatic charges. For example, as shown in FIG. 4A, the conductive pattern 122 may include a long linear pattern 122a, or may include two or more parallelling metal wires 122b each connected to a base wire 122c, e.g., in a perpendicular way, which forms a comb shape. The conductive pattern 122 may include other shapes, e.g., circular shape 122d or non-circular shapes (including strip shape 122e or oval shape 122f), as shown in sub-figures (a), (b), (c), d), or (e) of FIG. 4A. In some implementations, the conductive pattern 122 includes one or more round shapes. For example, as shown in sub-figure (c) of FIG. 4A, the conductive pattern 122 may include multiple round shapes 122d that surround one another (as shown) or partially overlap and cross one another.

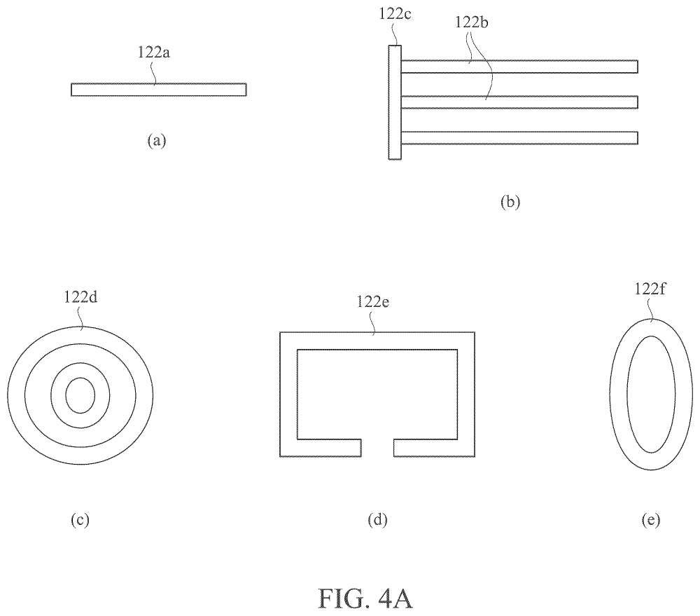

FIG. 5 shows embodiments of an ESD protection device. As shown in FIG. 5, the ESD protection device 120 includes a plurality of bonding pads 152 on a bonding layer 150. In some embodiments, the bonding pads 152 are exposed on the front surface 109. The bonding layer 150 is formed over the RDL layer 140 and functions to bond the die 100 to another die or to another semiconductor body, e.g., a carry substrate, in a 3D packaging process. Each bonding pad 152 is coupled to a conductive pad 132 through a via 154. The bonding pads 152 and the respective vias 154 are made of electrically conductive materials, e.g., copper.

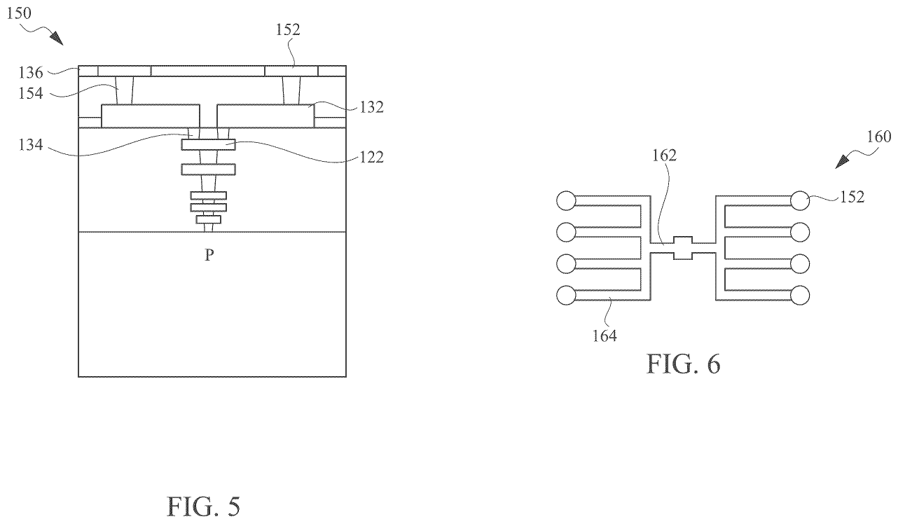

FIG. 6 shows in a top view a pattern of a conductive pad 132 and the related bonding pads 152. As shown in FIG. 6, in some embodiments, the conductive pad 132 may include one or more comb-shaped patterns or structures 160 and one or more bridge patterns or structures 162 that each connects to one or more or comb-shaped patterns or structures 160. One or more of the comb-shaped patterns or structure 160 or the bridge patterns or structures 162 of the conductive pad 132 are connected to the conductive pattern 122 through vias 134.

The comb-shaped pattern or structure 160 may include a plurality of comb fingers 164. In some embodiments, each of the bonding pads 152 is coupled to a comb finger 164 through a via 154. In some embodiments, multiple bonding pads 152 are coupled to a same comb finger 164. In some embodiments, one or more comb fingers 164 are not coupled to any bonding pad 152.

The comb fingers 164 may include a uniform shape, e.g., a rectangular shape, or may include varied shapes. For example, a comb-shaped pattern of a conductive pad 132 may include comb fingers 164 with non-uniform shapes and varied finger lengths or other dimensions, which may be configured based on maps of ESD charges on various surface regions of the surface 109 and/or on various surface regions of another semiconductor die or body to be bonded to the die 100 in a packaging process.

In some embodiments, an ESD device may include only the comb-shaped pattern or structure 160 on the RDL layer 130 and may not include a conductive pattern 122 on the top metallization level. For example, the interconnect structure 124 may include metal portions of the top metallization level and connect directly to the conductive pad 132 on the RDL layer 130, which includes comb-shaped pattern or structure 160.

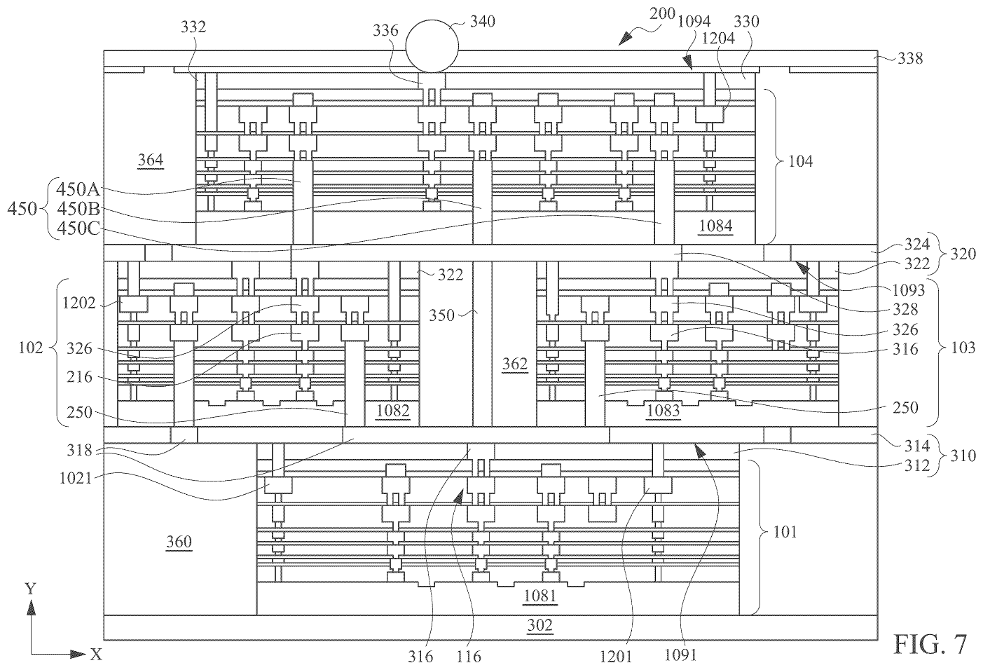

FIG. 7 is a cross-sectional view of a 3D package, e.g., an SoIC package, having a die stack 200, according to various embodiments of the present disclosure. Referring to FIG. 7, the die stack 200 includes a first semiconductor die 101, a second semiconductor die 102, a third semiconductor die 103, and a fourth semiconductor die 104, disposed in a stacked arrangement. For example, the second semiconductor die 102 and third semiconductor die 103 may be stacked on respective portions of the first semiconductor die 101. The fourth semiconductor die 104 may be stacked on respective portions of the second semiconductor die 102 and third semiconductor die 103. For example, the first semiconductor die 101, second semiconductor die 102, third semiconductor die 103, and fourth semiconductor die 104 may be stacked in a vertical direction Y, with the second semiconductor die 102 and third semiconductor die 103, collectively being disposed adjacent to one another in a horizontal direction X. For example, the second semiconductor die 102 and third semiconductor die 103 may be disposed in the same horizontal plane, while the first semiconductor die 101 may be disposed in a different horizontal plane and the fourth semiconductor die 104 may be disposed in yet another different horizontal plane.

In some embodiments, the first semiconductor die 101 may be disposed on a wafer or a carry substrate 302, which may or may not be removed when the die stack 200 is assembled with other device components.

One or more of the first semiconductor die 101, second semiconductor die 102, third semiconductor die 103, and fourth semiconductor die 104 may be similar to the first semiconductor die 100 of FIG. 1. For example, oner or more of semiconductor dies 101, 102, 103, 104 may include an ESD protection device 120, shown as 1201, 1202, 1203, 1204 with respect to semiconductor dies 101, 102, 103, 104. As such, previously described elements will not be described again in detail. The first semiconductor die 101, second semiconductor die 102, third semiconductor die 103, and fourth semiconductor die 104 may be independently selected from, for example, a SoIC die, a 3DIC die, a processor die, a power management die, a logic die, a communication management die (such as a baseband die), or combinations thereof. In some embodiments, the first semiconductor die 101, second semiconductor die 102, third semiconductor die 103, and fourth semiconductor die 104 may each be random access memory (RAM) dies, such as SRAM or DRAM chips. The first semiconductor die 101, second semiconductor die 102, third semiconductor die 103, and fourth semiconductor die 104 may be collectively or individually connected to a logic die, or other external device such as a printed circuit board, etc., via one or more metal bumps 340. In some embodiments one of the first semiconductor die 101, second semiconductor die 102, third semiconductor die 103, and fourth semiconductor die 104 may be a logic chip (e.g., logic die), and the remainder of the first semiconductor die 101, second semiconductor die 102, third semiconductor die 103, and fourth semiconductor die 104 may be memory dies or chips. The first semiconductor die 101 has a first semiconductor substrate 1081. The second semiconductor die 102 has a second semiconductor substrate 1082. The third semiconductor die 103 has a third semiconductor substrate 1083. The fourth semiconductor die 104 has a fourth semiconductor substrate 1084.

A first dielectric encapsulation (DE) layer 360 may surround the first semiconductor die 101, a second DE layer 362 may surround the second semiconductor die 102 and third semiconductor die 103. A third DE layer 364 may surround the fourth semiconductor die 104. In some embodiments, the first DE layer 360, second DE layer 362, and third DE layer 364 may be formed of a molding compound, silicon oxide, silicon nitride, or a combination thereof. The molding compound may include a resin and a filler. The first DE layer 360, second DE layer 362, and third DE layer 364 may be formed by spin-coating, lamination, deposition, or the like. Each of the first DE layer 360, second DE layer 362, and third DE layer 364 may be formed of the same material. In other embodiments, each of the first DE layer 360, second DE layer 362, and third DE layer 364 may be formed of different materials. In yet other embodiments, some of first DE layer 360, second DE layer 362, and third DE layer 364 may be formed of the same materials, while other DE layers may be formed of a different material. In a similar fashion, the DE layers may be formed by the same process, different processes or a combination thereof.

The die stack 200 may include a first bonding structure 310 configured to bond the first semiconductor die 100 to the second semiconductor die 102 and third semiconductor die 103. A second bonding structure 320 may be configured to bond the second semiconductor die 102 and third semiconductor die 103, to the fourth semiconductor die 104. A third bonding structure 330 may be disposed on a front side of the fourth semiconductor die 104, and a passivation layer 338 may be formed on the third bonding structure 330.

For example, the first bonding structure 310 may include a first front side bonding layer 312 disposed on a front side of the first semiconductor die 101. A first backside bonding layer 314 disposed on the first front side bonding layer 312, as well as the back sides of the respective second semiconductor die 102 and third semiconductor die 103, and the first DE layer 360. The second bonding structure 320 may include a second front side bonding layer 322 disposed on front sides of the respective second semiconductor die 102 and third semiconductor die 103. The second bonding structure 320 may also include a second backside bonding layer 324 disposed on the second front side bonding layer 322, a back side of the fourth semiconductor die 104, and the second DE layer 362.

The first front side bonding layer 312 may include one or more first layer bonding pads 316. The first backside bonding layer 314 may include a first RDL structure 318. The second front side bonding layer 322 may include second layer bonding pads 326. The second backside bonding layer 324 may include a second RDL structure 328. The third bonding structure 330 may include a third front side bonding layer 332. The third bonding structure may also include one or more third layer bonding pads 336 formed within the third front side bonding layer 332.

The front side bonding layers shown in FIG. 7 may be a same layer as the bonding layer 150 of FIG. 5 or may be a different or separate bonding layer.

The first layer bonding pads 316, second layer bonding pads 326, third layer bonding pads 336 and/or first RDL structure 318, and second RDL structure 328 may include an electrically conductive metal, such as tungsten (W), copper (Cu), a copper alloy, aluminum (Al), an aluminum alloy, or a combination thereof. Other suitable electrically conductive metals are within the contemplated scope of disclosure. In some embodiments, the electrically conductive metal may include copper at an atomic percentage greater than 80%, such as greater than 90% and/or greater than 95%, although greater or lesser percentages of copper may be used. Other suitable pad materials may be within the contemplated scope of disclosure. In some embodiments, the third layer bonding pads 336 may be under bump metallization (UBM) pads for mounting conductive connectors, such as metal pillars, micro-bumps, metal bumps or the like.

The first layer bonding pads 316, second layer bonding pads 326, third layer bonding pads 336 and/or first RDL structure 318, and second RDL structure 328 may be formed by a dual-Damascene processes, or by one or more single-Damascene processes, for example. Single-Damascene processes generally form and fill a single feature with copper per Damascene stage. Dual-Damascene processes generally form and fill two features with copper at once, e.g., a trench and overlapping through-hole may both be filled with a single copper deposition using dual-Damascene processes. In alternative embodiments, the first layer bonding pads 316, second layer bonding pads 326, third layer bonding pads 336 and/or first RDL structure 318, and second RDL structure 328 may be formed by an electroplating process.

The die stack 200 may include a through dielectric via (TDV) structure 350 that extends through the second DE layer 362 and electrically connects the first RDL structure 318, and/or second RDL structure 328. The TDV structure 350 may be formed of a metal, such as tungsten (W), copper (Cu), a copper alloy, aluminum (Al), an aluminum alloy, or a combination thereof. For example, the TDV structure 350 may include copper at an atomic percentage greater than 80%, such as greater than 90% and/or greater than 95%, although greater or lesser percentages of copper may be used.

The first RLD structure 318 may be configured to electrically connect one or more conductive elements of the first semiconductor die 101 to conductive elements of the second semiconductor die 102 and third semiconductor die 103. For example, the first RLD structure 318 may electrically connect metal features 116 of the first semiconductor die 101 to TSV structures 250 of the second semiconductor die 102 and third semiconductor die 103. The TDV structure 350 may electrically connect the metal features 116 of the first semiconductor die 101 to a TSV 450 of the fourth semiconductor die 104.

The second RLD structure 328 may be configured to electrically connect conductive elements of the second semiconductor die 102 and third semiconductor die 103 to one or more conductive elements of the fourth semiconductor die 104. For example, the second RLD structure 328 may electrically connect metal features 216 of the second semiconductor die 102 and metal features 316 of the third semiconductor die 103 to respective TSV structures 450 of the fourth semiconductor die 104.

Accordingly, the second semiconductor die 102, third semiconductor die 103, and fourth semiconductor die 104 may include one or more respective TSV structures 250, 450 for establishing electrical interconnections. For example, in some embodiments, the fourth semiconductor dies 104 may include a first TSV structure 450A, a second TSV structure 450B, and a third TSV structure 450C that each extend through the fourth semiconductor substrate 148. The first TSV structure 450A may be electrically connected to the second semiconductor die 102, the second TSV structure 450B may be electrically connected to the first semiconductor die 101 via the TDV structure 350, and the third TSV structure 450C may be electrically connected to the third semiconductor die 103. In some embodiments, the first semiconductor die 101 may omit a TSV structure, since it is not required for establishing electrical interconnections with the other dies such as the second semiconductor die 102, third semiconductor die 103, and fourth semiconductor die 104.

In some embodiments, the first die 101 includes ESD protection devices 1201 having a conductive pattern adjacent to the interface 1091 between the first die 101 and the second die 102 and between the first die 101 and the third die 103, for example between the front side bonding layer 312 and the back side bonding layer 314. The second die 102 includes an ESD protection device 1202 having a conductive pattern adjacent to the interface 1092 between the second die 102 and the fourth die 104. The third die 103 includes an ESD protection device 1203 having a conductive pattern adjacent to the interface 1093 between the third die 103 and the fourth die 104. The fourth die 104 includes an ESD protection device 1204 having a conductive pattern adjacent to the interface 1094 between the fourth die 104 and the passivation layer 338.

These ESD protection devices function to absorb or channel the ESD charges generated in the assembly process involving those dies. For example, the ESD charges generated in the spin cleaning or die picking operations may be caught and absorbed by the ESD protection devices by channeling the charges to the substrate 108 (1081, 1082, 1083, 1084) or ground terminals in those dies, such that the ESD charges will not accumulate and stay on the surfaces of the relevant dies and cause detrimental effects such as plasm induce damage (PID) effect.

FIG. 7 shows that the die 101 is coupled to the carry substrate 302 by a back side of the substrate 1081, the die 102 and the die 103 are coupled to the front surface of the die 101 by back sides of the substrates 1082, 1083, respectively, and the die 104 is coupled to the front surfaces of the dies 102, 103 by a back side of the substrate 1084. Further, in FIG. 7, only one of the dies includes ESD protection devices 120 (1201, 1202, 1203, 1024) adjacent to the interface 109 (1091, 1092, 1093, 1094) between dies or between a die and another body. Those example embodiments do not limit the scope of the disclosure.

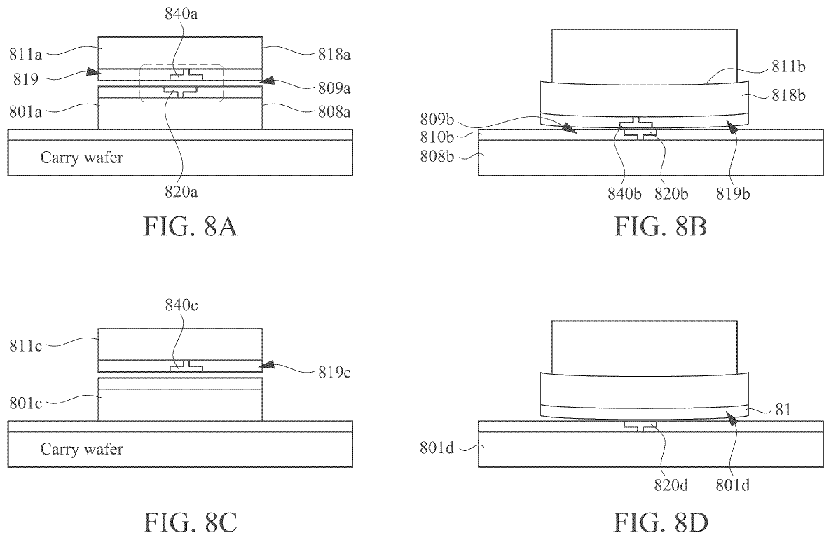

FIGS. 8A-8D show example die stack configurations. In FIG. 8A, a first semiconductor die 801a includes a base substrate 808a and a front surface 809a opposite to the base substrate 808a; and a second semiconductor die 811a includes a base substrate 818a and a front surface 819a opposite to the base substrate 8181a. The first die 801a and the second die 811a are stacked over one another with the front surfaces 809a and 819a facing one another. The first die 801a includes an ESD protection device 820a adjacent to the front surface 809a; and the second die 811a includes an ESD protection device 840a adjacent to the front surface 819a. That is, each of the first die 801a and the second die 811a includes an ESD protection device adjacent to the interface between the two dies 801a, 811a.

In FIG. 8B, a carry wafer or substrate 801b includes a base substrate 808b and a front surface 809b opposite to the base substrate 808a; and a semiconductor die 811b includes a base substrate 818b and a front surface 819b opposite to the base substrate 818b. The carry substrate 801b and the die 811b are stacked over one another with the front surfaces 809b and 819b facing one another. The carry substrate 801b includes an ESD protection device 820b adjacent to the front surface 809b; and the die 811b includes an ESD protection device 840b adjacent to the front surface 819b. That is, each of the carry substrate 801b and the second die 8112a includes an ESD protection device adjacent to the interface between the carry substrate 801b and the die 811b.

In FIG. 8C, the stack of dies are similar to the configuration shown in FIG. 8A, except that only one of the dies, here die 811c, includes an ESD protection device 840c adjacent to the front surface 819c of the die 811c that interfaces with the die 801c.

In FIG. 8D, the stack of dies are similar to the configuration shown in FIG. 8B, except that only the carry substrate 801d includes an ESD protection device 820d adjacent to the front surface 809d of the carry substrate 801d that interfaces with the die 811d. The die 811d does not include an ESD protection device adjacent to the interface between the die 811d and the carry substrate 801d.

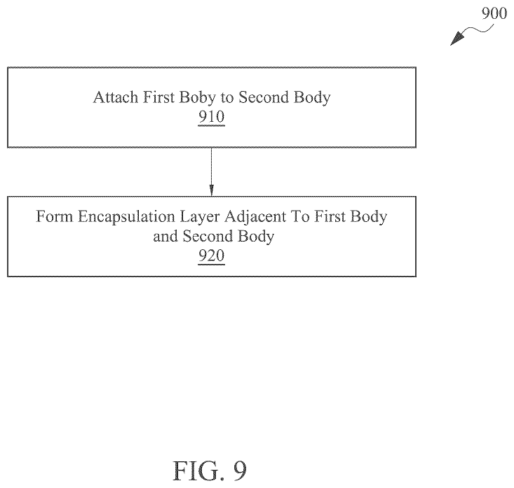

FIG. 9 shows a flow diagram of a process 900. As shown in FIG. 9, in operation 910, a first body is attached to a second body, using, e.g., suction tips of a die handling tool. As shown in FIGS. 1 and 8A-8D, for example, the first body may have a first surface and a first base opposite to the first surface, and the second body may have a second surface and a second base opposite to the second surface. The second surface interfaces with the first surface. One or more of the first body or the second body may include an ESD protection device. The ESD protection device includes a conductive pattern in the body and adjacent to the respective surface and an interconnect structure connected to the conductive pattern and extending toward the base. The ESD protection device functions to absorb ESD charges present on one or more of the first surface or the second surface.

In operation 920, an encapsulation layer is formed adjacent to the first body and the second body. For example, FIG. 7 shows encapsulation layers 360, 362, 364. The encapsulation layer can be filed by various approaches, which are all included in the scope of the disclosure.

In an embodiment, a package structure includes a plurality of semiconductor dies stacked over one another and an encapsulant adjacent to the plurality of dies. The plurality of semiconductor dies include a first die and a second die, a first surface of the first die facing a second surface of the second die. The first die includes an ESD protection device. The ESD protection device includes a conductive pattern adjacent to the first surface of the first die and an interconnect structure connected to the conductive pattern and extending toward a first semiconductor substrate of the first die. And the first semiconductor substrate of the first die is opposite to the first surface of the first die.

In an embodiment, a structure includes a first body having a first surface and a first base opposite to the first surface and a second body having a second surface and a second base opposite to the second surface. The second surface interfaces with the first surface of the first body. The first body includes a first ESD protection device. The first ESD protection device includes a first conductive pattern in the first body and adjacent to the first surface and a first interconnect structure connected to the first conductive pattern and extending toward the first base.

In an embodiment, a method includes attaching a first body to a second body. The first body includes a first surface and a first base opposite to the first surface. The second body includes a second surface and a second base opposite to the second surface. The second surface interfaces with the first surface. The first body includes a first ESD protection device. The first ESD protection device includes a first conductive pattern in the first body and adjacent to the first surface and a first interconnect structure connected to the first conductive pattern and extending toward the first base. The method also includes forming an encapsulation layer adjacent to the first body and the second body.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a plurality of semiconductor dies stacked over one another, the plurality of semiconductor dies including a first die and a second die, a first surface of the first die facing a second surface of the second die; and
an encapsulant adjacent to the plurality of dies,
wherein the first die includes an ESD protection device, the ESD protection device including a conductive pattern adjacent to the first surface of the first die and an interconnect structure connected to the conductive pattern and extending toward a first semiconductor substrate of the first die, the first semiconductor substrate of the first die opposite to the first surface of the first die.

2. The package structure of claim 1, wherein the interconnect structure reaches the first semiconductor substrate of the first die.

3. The package structure of claim 1, wherein the ESD protection device includes a bonding conductive structure exposed on the first surface of the first die, the bonding conductive structure coupled to the conductive pattern.

4. The package structure of claim 1, wherein the first die includes a redistribution layer below the first surface of the first die, the conductive pattern is between the redistribution layer and the first semiconductor substrate of the first die, and the redistribution layer includes a conductive pad pattern coupled to the conductive pattern.

5. The package structure of claim 4, wherein the ESD protection device includes a bonding conductive structure exposed on the first surface of the first die, the first bonding conductive structure coupled to the conductive pattern through the conductive pad pattern of the redistribution layer.

6. The package structure of claim 1, wherein the first die includes a redistribution layer below the first surface of the first die and over the interconnect structure, the redistribution layer including a conductive layer, and the conductive pattern is a part of the conductive layer of the redistribution layer.

7. The package structure of claim 1, wherein the interconnect structure is coupled to a ground terminal of the first die.

8. The package structure of claim 1, wherein the interconnect structure is coupled to a doped region in the first semiconductor substrate of the first die.

9. The package structure of claim 1, wherein the conductive pattern includes two comb patterns and a bright pattern coupling the two comb patterns.

10. The package structure of claim 1, wherein the conductive pattern includes a comb shape having a plurality of fingers.

11. The package structure of claim 10, wherein the ESD protection device includes a bonding conductive structure exposed on the first surface of the first die, the bonding conductive structure including a plurality of bonding pads each coupled to a finger of the plurality of fingers.

12. The package structure of claim 10, wherein a first finger and a second finger of the plurality of fingers have different dimensions.

13. The package structure of claim 10, wherein a first finger and a second finger of the plurality of fingers have different shapes.

14. The package structure of claim 1, wherein the conductive pattern is fully embedded within the first die and separated from the first surface of the first die by an dielectric layer.

15. The package structure of claim 1, wherein the conductive pattern is part of a metallization level of the first die.

16. A structure, comprising:
a first body having a first surface and a first base opposite to the first surface; and
a second body having a second surface and a second base opposite to the second surface, the second surface interfacing with the first surface of the first body,
wherein the first body includes a first ESD protection device, the first ESD protection device including a first conductive pattern in the first body and adjacent to the first surface and a first interconnect structure connected to the first conductive pattern and extending toward the first base.

17. The structure of claim 16, wherein the first body is a first semiconductor die and the second body is a carry substrate.

18. The structure of claim 16, wherein the first body is a carry substrate and the second body is a first semiconductor die.

19. The structure of claim 16, wherein the second body includes a second ESD protection device including a second conductive pattern in the second body and adjacent to the second surface and a second interconnect structure connected to the second conductive pattern and extending toward the second base.

20. A method, comprising:
attaching a first body to a second body, the first body having a first surface and a first base opposite to the first surface, the second body having a second surface and a second base opposite to the second surface, the second surface interfacing with the first surface, the first body including a first ESD protection device, the first ESD protection device including a first conductive pattern in the first body and adjacent to the first surface and a first interconnect structure connected to the first conductive pattern and extending toward the first base; and
forming an encapsulation layer adjacent to the first body and the second body.
